(19) United States
(12) Patent Application Publication
(10) Pub. No.: US 2012/0035057 A1
(43) Pub. Date: Feb. 9, 2012

(54) ROOM-TEMPERATURE SUPERCONDUCTIVE-LIKE DIODE DEVICE

(76) Inventors: Alexandre Bratkovski, Mountain View, CA (US); Iakov Kopelevitch, Mountain View, CA (US)

(21) Appl. No.: 12/849,712

(22) Filed: Aug. 3, 2010

(51) Int. Cl. H01B 12/06; H01L 39/12; G01R 27/08; H01L 39/24

(52) U.S. Cl. 505/160; 505/150; 505/235; 505/234; 505/470; 257/35; 257/E39.006; 324/713

(57) ABSTRACT

Methods and apparatus characterized by distinct operating modes are provided. A thin graphite material defined by graphene layers is supported on a silicon substrate. The graphite material is defined by edge sites at the interface with the silicon. The graphite material is characterized by electrical superconductive-like behavior at room-temperatures while electrical current flows there through in a first direction. The graphite material is further characterized by a transition to Ohmic behavior while electrical current flows there through in a second direction opposite to the first. Devices exhibiting diode-like behavior can be formed accordingly.

### BACKGROUND

Electronic devices and constructs of various types are used to perform a myriad of functions. New types of devices and electronic components having new or improved functionality are continuously sought. Developments in this area are ongoing as an understanding of materials and their respective, properties progresses. The present teachings are directed to the foregoing endeavors.

### BRIEF DESCRIPTION OF THE DRAWINGS

The present embodiments will now be described, by way of example, with reference to the accompanying drawings, in which:

FIG. 1 is an end elevation view depicting select details of a device according to one embodiment;

FIG. 2 is an isometric view depicting a device according to one embodiment;

FIG. 3 is a current-versus-voltage signal diagram of a device according to one embodiment;

FIG. 4 is a block diagram depicting a circuit according to another embodiment.

FIG. 5 is flow diagram depicting a method according to one embodiment.

### DETAILED DESCRIPTION

### Introduction

Methods and apparatus characterized by distinct electrical operating modes are provided. A diode-like device includes a thin graphite material defined by graphene layers supported in contact with a silicon wafer or other substrate. The graphite is defined by edge sites at the interface with the silicon. The graphite material is characterized by electrical superconducting-like behavior at room-temperatures when electrical current is communicated there through in a first direction. The graphite material is further characterized by a transition to Ohmic behavior when electrical current is communicated there through in a second direction opposite to the first. The diode-like device thus exhibits two distinctly different operating modes in accordance with electrical current flow.

In one embodiment, an apparatus includes a substrate and a graphite material supported by the substrate. The graphite material is configured to define a plurality of edge sites at respective interface locations with the substrate. The apparatus is characterized by superconducting-like electrical conduction when an electrical current is communicated there through in a predetermined direction.

In another embodiment, a device includes a graphite material in contact with a substrate. The device is configured to operate in a first mode characterized by about zero voltage drop when an electrical current is communicated through the device in a first polarity. The device is also configured to operate in a second mode characterized by an about linear relationship between voltage drop and electrical current when an electrical current is communicated through the device in a second polarity opposite to the first polarity.

In still another embodiment, a machine or system includes a diode-like device characterized by a superconductive-like operating mode and an Ohmic operating mode and a non-linear operating mode.

In another embodiment, a method includes supporting a graphite material on a substrate. The graphite material is defined by plural graphene layers. The graphite material is characterized by a plurality of edge sites at respective interface locations with the substrate. The graphite material is further characterized by near electrical superconductivity when an electrical current is communicated by way of the graphite material in a predetermined direction.

### First Illustrative Embodiment

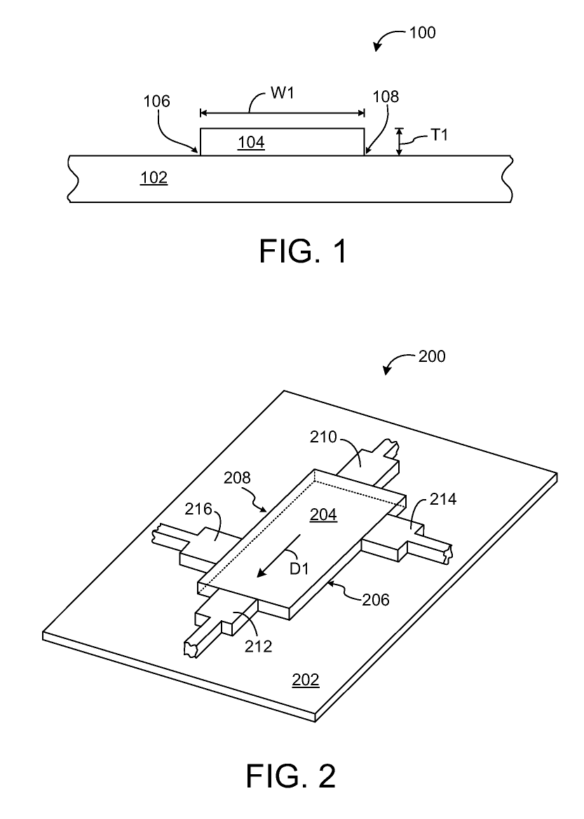

Reference is now directed to FIG. 1, which depicts an end elevation view of selected details of a device 100 according to one embodiment. The device 100 is illustrative and non-limiting with respect to the present teachings. Thus, other devices, apparatus or systems can be configured or operated in accordance with the present teachings.

The device 100 includes a silicon substrate 102. The silicon substrate 102 is defined by a wafer, or a portion of a wafer. The silicon substrate 102 is substantially pure (i.e., semiconductor grade) and has not been intentionally altered or “doped” by way of another atomic species, by ion implantation or other techniques. One having ordinary skill in the semiconductor and related arts is familiar with silicon wafers and further elaboration is not needed for an understanding of the present teachings. The present teachings contemplate that suitable material other than silicon can be used as substrates, as well.

The device 100 includes a graphite entity (graphite) 104 supported in contact with the silicon substrate 102. The graphite 104 includes or is defined by a plurality of graphene layers. The graphite 104 is further defined by a width “W1” and a thickness “T1”. The graphite 104 is further defined by a pair of opposite edge lines 106 and 108, respectively. Each of the edge lines 106 and 108 runs parallel to a length-wise aspect of the graphite 104, extending into the drawing sheet as seen by a viewer. Each of the edge lines 106 and 108 is defined by a respective plurality of “edge sites” at interface points with the silicon substrate 102.

The device 100 depicts a particular orientation in which the graphite 104 is disposed above or upon the silicon substrate 102. However, it is to be understood that the present teachings also contemplate disposition of graphite material generally beneath a substrate (i.e., a “superstrate”) or in side-by-side orientation therewith. Thus, one of ordinary skill in the art shall recognize that the present teachings are directed to graphite in contact with an appropriate interface material (e.g., silicon, etc.). The specific orientation between the graphite and such material is not germane to purposes herein. In the interest of clarity, the term “substrate” is used herein to refer to the material in interface defining-contact with the graphite, regardless of orientation.

An edge site refers to a location within a hexagonal ring of covalently bonded carbon atoms, specifically, a carbon atom that is along an edge or periphery of a graphene layer. Such an edge site carbon atom is bonded to one or two other carbon atoms, while all other (non-edge site) carbon atoms within that graphene layer are bonded to three other carbon atoms. Additional information regarding edge sites in graphene layers is provided in: Peculiarized Localized State at ZigZag Graphite Edge, Mitsutaka Fujita et al., Journal of the Physical Society of Japan, Vol. 65, No. 7, July 1996, pages 1920-1923.

According to the present teachings, each respective edge site along the edge lines 106 and 108, at the interface with the silicon substrate 102, is characterized by hosting a (non-dissipative) current vortex or a (non-dissipative) current anti-vortex induced by an electrical current through the graphite 104 (vortices are analogous to those observed in superconducting films.). Whether a particular edge site hosts a vortex or an anti-vortex is dependent upon the orientation of that edge site with the electrical current direction or polarity through the graphite 104. Additional information regarding vortices and anti-vortices is accessible on the Internet via the following Uniform Resource Locator (URL): http://en.wikipedia.org/wiki/Abrikosov_vortex.

In a first condition, applied electrical current flows in a first direction through the graphite and the vortices and anti-vortices, once formed, are drawn toward each other and are thus annihilated. This formation and annihilation process is ongoing and sustained while current flows in the first condition. The graphite exhibits a non-linear relationship between applied current and voltage drop for a range of low-levels currents under the first condition. The graphite then exhibits a nearly linear or Ohmic relationship between current and voltage drop at higher-level current under the first condition.

In a second condition, applied electrical current flows in a second direction opposite to the first and the vortices and anti-vortices, once formed, are sustained or “pinned” in place at the respective edge sites and do not annihilate each other. The graphite exhibits electrical superconductive-like behavior under the second condition. That is, there is zero or nearly zero voltage drop over a wide range of applied current levels under the second condition. Such superconductive-like behavior is exhibited at room-temperatures (e.g., three-hundred degrees Kelvin, etc.) and does not require cryogenic cooling, external sources of magnetic fields, etc.

In one embodiment, the graphite 104 is characterized by a width “W1” of about zero-point-five millimeters and a thickness “T1” of about two-hundred fifty nanometers (1 nanometer=10⁻⁹ meters). The immediate foregoing embodiment is further characterized by a translucent or nearly transparent quality of the graphite 104. Other embodiments with other graphite dimensions can also be used.

### Second Illustrative Embodiment

Attention is now directed to FIG. 2, which depicts an isometric view of a device 200 according to one embodiment. The device 200 is illustrative and non-limiting with respect to the present teachings. Thus, other devices, apparatus or systems can be configured or operated in accordance with the present teachings.

The device 200 includes a silicon substrate or wafer 202. The silicon substrate 202 is substantially pure and has not been intentionally altered or “doped”. Various devices and entities (not shown) can be optionally supported by the silicon substrate 202 or formed such that the silicon substrate 202 is a portion thereof. Circuitry, or an integrated circuit or portion thereof, can thus be defined. Such optional entities and formations are not germane to understanding the present teachings.

The device 200 also includes a graphite portion 204 in contact with the silicon substrate 202. The graphite portion 204 is defined by a first contact edge 206 and a second contact edge 208. Each of the contact edges 206 and 208 includes a respective plurality of edge sites, where the periphery of the “bottom” graphene layer contacts (or interfaces with) the silicon substrate 202.

The device 200 also includes a first current drive electrode 210 and a second current drive electrode 212. Each of the electrodes 210 and 212 is in electrically conductive contact with or is electrical coupled to the graphite portion 204. The electrodes 210 and 212 can be formed from any suitable electrically conductive material such as, for non-limiting example, platinum, gold, aluminum, etc. Other suitable materials can also be used. The electrodes 210 and 212 define a pair configured to communicate an electrical current through the graphite 204 by way of an external source (not shown).

The device 200 further includes a first voltage sense electrode 214 and a second voltage sense electrode 216. Each of the electrodes 214 and 216 is in electrically conductive contact with or is electrical coupled to the graphite portion 204. The electrodes 214 and 216 can be formed from any suitable electrically conductive material such as, for non-limiting example, platinum, gold, aluminum, etc. Other suitable materials can also be used. The electrodes 214 and 216 define a pair configured to sense an electrical potential or voltage exhibited across the graphite 204 during various operating conditions. The voltage sense electrodes 214 and 216 are optional. In another embodiment, voltage is sensed by way of the current drive electrodes 210 and 212 and the voltage sense electrodes 214 and 216 are omitted.

The graphite portion 204 is about in the form of a rectangular box or parallelepiped. However, it is to be understood that graphite portions in accordance with the present teachings can have any number of form factors and shapes. In one embodiment, the graphite portion 204 is defined by respective width and thickness dimensions about equal to those described above for the graphite 104. Other suitable dimensions can also be used. The device 200 is also referred to as a “room-temperature superconductive-like diode” or RTSD 200.

### First Illustrative Performance Curve

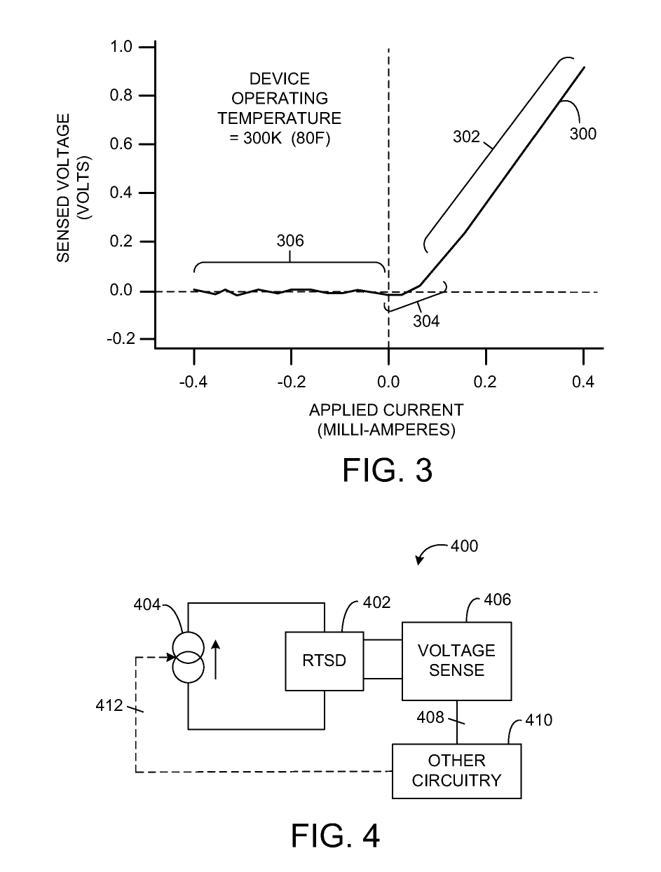

FIG. 3 depicts a current-versus-voltage curve 300 in accordance with the present teachings. The curve 300 is illustrative and non-limiting in nature. Thus, other embodiments characterized by other performance or operating curves can also be defined and used. For purposes of illustration, it is assumed that the curve 300 depicts averaged performance of the device 200 when operating at “room-temperature” (i.e., about eighty degrees Fahrenheit). Reference is also made to FIG. 2 during the following description.

The curve 300 is characterized by a linear or nearly linear portion 302. The curve portion 302 is also referred to as an Ohmic operating region. The portion 302 depicts applied current versus sense voltage drop for the device 200 when the applied current is greater than about zero-point-one milli-Amperes. The direction of current flow corresponding to the portion 302 is in a direction opposite to the arrow “D1”. That is, electron flow is from electrode 212 toward electrode 210. Sensed voltage is between electrodes 214 and 216.

The curve 300 is also characterized by a non-linear or transition-zone portion 304. The portion 304 depicts applied current versus voltage drop for the device 200 when the applied current is greater than zero and less than about zero-point-one milli-Amperes. The direction of current flow corresponding to the portion 304 is in a direction opposite to the arrow “D1”. Sensed voltage is between electrodes 214 and 216.

The curve 300 is further characterized by a superconductive-like portion 306. The portion 306 depicts a zero or nearly zero voltage drop for the device 200 when an applied current is greater than zero. The direction of current flow is in the direction indicated by the arrow “D1”. Thus, electron flow is from electrode 210 toward electrode 212. Sensed voltage is between electrodes 214 and 216.

The curve 300 is illustrative and non-limiting, and is derived from an average of six datasets measured of a prototype analogous to the device 200. Devices according to the present teachings exhibit a diode-like behavior, characterized by an essentially zero voltage drop while being driven in a first polarity, and a transition to Ohmic behavior while being driven in a second polarity opposite to the first.

### First Illustrative Circuit

FIG. 4 is a block diagram depicting a circuit 400 in accordance with one embodiment. The circuit 400 is illustrative and non-limiting. Other circuits, devices and apparatus can be configured and operated in accordance with the present teachings.

The circuit 400 includes a room-temperature superconductive-like diode or RTSD 402. The RTSD 402 is defined and configured according to the present teachings. Thus, the RTSD 402 is characterized by a first operating mode that exhibits superconducting or nearly superconducting behavior when electrical current is communicated to the RTSD 402 in a first direction. The RTSD 402 is also characterized by a second operating mode that exhibits a non-linear transition to Ohmic behavior when electrical current is communicated to the RTSD 402 in a second direction opposite to the first. In one embodiment, the RTSD 402 is substantially equivalent to the device 200.

The circuit 400 also includes a current source 404. The current source 404 can be of fixed or variable operation and is configured to communicate an electrical current through the RTSD 402. Specifically, the current source 404 is configured to selectively provide (or drive) electrical current in either of two opposite polarities and at respectively variable levels.

The circuit 400 also includes voltage sense circuitry 406. The sense circuitry 406 is configured to detect a voltage drop across or exhibited by the RTSD 402 during normal, current-driven operations thereof. The sense circuitry 406 is further configured to provide a corresponding analog or digital signal or data 408 corresponding to the sensed voltage drop.

The circuit 400 also includes other circuitry 410. The other circuitry 410 can be variously defined and can include, without limitation, a microprocessor or microcontroller, memory or other storage media, communications circuitry, a battery or other energy source, signal processing circuitry, an application specific integrated circuit (ASIC), etc. In one optional embodiment, the other circuitry 410 includes a controller configured to control operation of the current source 402 by way of signaling 412. Other options or other circuitry 410 can also be used.

The circuit 400 is general and illustrative of any number of configurations that can use one or more RTSDs (e.g., 402) according to the present teachings. Thus, numerous apparatus and systems can be configured using devices as taught herein. For non-limiting example, room-temperature superconductive-like diode according to the present teachings can be applied to enhancing sensitivity of superconducting quantum interference devices (i.e., SQUIDs), as well as improving the performance of active and passive (so-called ‘fluxonic’) devices by removing unwanted trapped vortices from those devices using the vortex rectification effect.

### First Illustrative Method

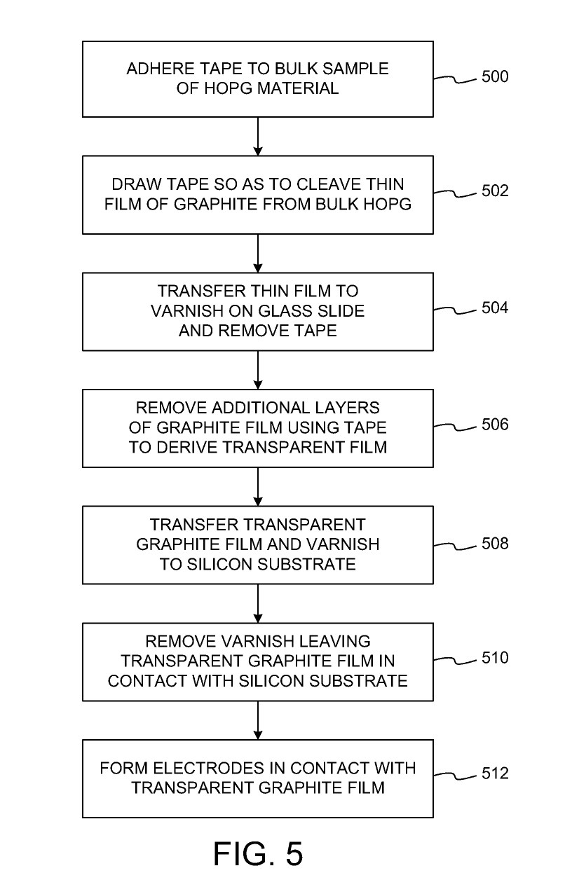

Attention is now directed to FIG. 5, which depicts a flow diagram of a method according to one embodiment of the present teachings. Specifically, the method of FIG. 5 depicts at least one way to prepare a prototype device according to the present teachings. The method of FIG. 5 includes particular operations and order of execution. However, other methods including other operations, omitting one or more of the depicted operations, and/or proceeding in other orders of execution can also be used according to the present teachings. Thus, the method of FIG. 5 is illustrative and non-limiting in nature.

At 500, a piece of adhesive tape is adhered to a bulk sample of highly ordered pyrolytic graphite (HOPG). Conventional transparent adhesive tape can be used. For non-limiting example, such a bulk sample has initial dimensions of five millimeters width by five millimeters length by one millimeter thickness. Such a sample of material is available from SPI SUPPLIES, INC., WEST CHESTER, PENNSYLVANIA, USA.

At 502, the adhesive tape is drawn away so as to cleave a thin film of graphite material away from the bulk HOPG sample. For purposes of the present example, a graphite film adheres to the tape and is drawn away or cleaved from the bulk sample by way of the adhesive action of the tape.

At 504, the thin film of graphite is transferred to a varnish material borne by a glass slide and the tape is removed. For purposes of the present example, the graphite film is carefully pressed into contact with the varnish and the adhesive tape is removed by way of an acute angle-drawing motion. The varnish exhibits a superior adhesive force to that of the tape, thus the graphite material is left intact—or nearly so—on the varnish.

At 506, additional layers of the thin film of graphite are removed using adhesive tape to derive a transparent graphite film. For purposes of the present example, one or more portions of adhesive tape are used to remove graphene layers until a thinner (reduced) portion of the graphite remains adhered to the varnish. This remaining HOPG portion is of a thickness of less than about two-hundred fifty nanometers, and preferably less than about one-hundred nanometers. Graphite at this thickness is incidentally characterized by a transparent or translucent quality.

At 508, the transparent graphite film and the varnish are transferred from the glass slide to a silicon substrate. In the present example, the graphite is adhered to a silicon wafer of normal, laboratory or semiconductor grade.

At 510, the varnish is removed leaving the transparent graphite in contact with the supporting silicon substrate. In the present example, the graphite material is now in direct contact with the silicon substrate. Several edge sites are present along two or more edges of the graphite, in contact with the supporting silicon. These edge sites can host vortices or anti-vortices, respectively, during normal operations.

At 512, electrodes are formed in contact with the graphite film. In the present example, electrodes of platinum are formed in contact with and at respective locations about the periphery of the graphitic film. These electrodes can then be used to electrically couple the graphite to external entities such as a current source, voltage measuring instrumentation, etc. Testing and or operation of the device thus formed can now be performed.

In general, and without limitation, the foregoing method describes preparation of a diode-like device according to the present teachings. Such a device is characterized by a superconductive-like operating mode when electrical current flows through the thin graphite in one direction. The device is further characterized by transition and Ohmic operating modes when electrical current flows through the thin graphite in the opposite direction.

The present teachings contemplate that numerous other suitable techniques can be used to prepare prototypes or working embodiments of diode-like devices. Thus, existing and future techniques can be used to form devices within the scope of the characteristics contemplated herein.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
a substrate; and
a graphite material supported by the substrate, the graphite material configured to define a plurality of edge sites at respective interface locations with the substrate, the apparatus characterized by superconducting-like electrical conductivity when an electrical current is communicated there through in a predetermined direction.

2. The apparatus according to claim 1, the apparatus characterized by the superconducting-like electrical conductivity at operating temperatures greater than minus one-hundred degrees Centigrade.

3. The apparatus according to claim 1, the substrate being defined by at least a portion of an undoped semiconductor wafer.

4. The apparatus according to claim 1 further comprising a first electrode electrically coupled to the graphite material and a second electrode electrically coupled to the graphite material, the first and second electrodes configured to communicate an electrical current through the graphite material.

5. The apparatus according to claim 4, at least the first or second electrode being formed from an electrically conductive material.

6. The apparatus according to claim 1, the graphite material being defined by a plurality of graphene layers.

7. The apparatus according to claim 1 further comprising a first electrode and a second electrode, the first and second electrodes being electrically coupled to the graphite material, the first and second electrodes configured to sense an electrical potential across the graphite material.

8. The apparatus according to claim 1, the graphite material further configured such that at least some of the edge sites host either a sustained superconducting-like current vortex or a sustained anti-vortex when an electrical current is communicated through the apparatus in the predetermined direction.

9. The apparatus according to claim 1, the apparatus further characterized by an Ohmic relationship between electrical current and electrical potential when an electrical current is communicated there through in a direction opposite to the predetermined direction.

10. A device including a graphite material in contact with a substrate, the device configured to:
operate in a first mode characterized by about zero voltage drop when an electrical current is communicated through the device in a first polarity; and
operate in a second mode characterized by an about linear relationship between voltage drop and electrical current when an electrical current is communicated through the device in a second polarity opposite to the first polarity.

11. The device according to claim 10 further comprising a pair of electrodes configured to communicate an electrical current through the graphite material.

12. The device according to claim 10 further comprising a pair of electrodes configured to sense a voltage exhibited by the graphite material.

13. The device according to claim 10, the graphite material characterized by a plurality of edge sites defined at respective interface locations with the substrate, at least some of the edge sites characterized by either a current vortex or a current anti-vortex that is induced and sustained by an electrical current during operation of the device in the first mode.

14. The device according to claim 10, the graphite material characterized by a plurality of graphene layers so as to define a graphite material thickness equal to or less than one hundred nanometers.

15. A machine, comprising:
A diode-like device characterized by a superconductive-like operating mode and an Ohmic operating mode and a non-linear operating mode.

16. The machine according to claim 15, the diode-like device characterized by the superconductive-like and the Ohmic and the non-linear operating modes while operating at temperatures greater than minus one hundred degrees Centigrade.

17. The machine according to claim 15, the diode-like device including a graphite material supported by a substrate, the graphite material defined by a plurality of edge sites located at respective interface points with the substrate, one or more of the edge sites characterized by hosting either a sustained vortex or a sustained anti-vortex when an electrical current flows through the graphite material along the interface points in a predetermined direction.

18. A method, comprising:
supporting a graphite material on a substrate, the graphite material defined by plural graphene layers, the graphite material characterized by a plurality of edge sites at respective interface locations with the substrate, the graphite material further characterized by superconducting-like electrical conductivity when an electrical current is communicated by way of the graphite material in a predetermined direction.

19. The method according to claim 18 further comprising:
flowing an electrical current by way of the graphite material in the predetermined direction; and
sensing about zero voltage drop exhibited by the graphite material in accordance with the superconducting-like electrical conductivity.
